(19) United States
(12) Patent Application Publication
(10) Pub. No.: US 2011/0316711 A1
(43) Pub. Date: Dec. 29, 2011

(54) Pocket grounding device without power socket

(75) Inventors: Lien-Hsun Ho, Taipei (TW); Hong-Lun Wang, Taipei (TW); Tung-Yuan Chen, Taipei (TW); Yuan-Liang Hsu, Taipei (TW)

(73) Assignee: CYBER POWER SYSTEMS INC.

(21) Appl. No.: 12/803,473

(22) Filed: Jun. 28, 2010

(51) Int. Cl. G08B 21/00; G01R 31/00

(52) U.S. Cl. 340/644; 324/508

(57) ABSTRACT

A pocket grounding device without power socket has a casing, an AC plug and a circuit board. The AC plug is mounted in the casing and electronically connected to the circuit board. The circuit board has a ground detecting circuit having three ports respectively connected to the AC plug, an electronic switch connected between to two of the ports and a controlling terminal thereof connected to the last port, and an indicator exposed to the casing. The indictor is driven to light according to an AC outlet of a power strip having good or bed grounding connection. Therefore, a user checks the indicator status to judge whether the AC power strip has good grounding connection.

### BACKGROUND OF THE INVENTION

1. Field of the Invention

The present invention relates to a grounding device, and more particularly to a pocket grounding device without power socket.

2. Description of Related Art

A general AC outlet has an AC line wire, AC neutral wire and ground wire. The ground wire is used to connect to ground and an electronic equipment does not have electric leakage condition to harm the user when the power plug of the electronic equipment inserts into the AC outlet having ground. However, the user does not ensure whether the ground connection is good or not, since the ground wire is hidden in a casing of the AC outlet. Therefore, an apparatus that provides electronic equipment with a reliable ground, AC line and AC neutral connections.

With reference to FIG. 5, a conventional grounding apparatus (30) is proposed and has a housing (31), an AC plug (32), a power socket (33) and a ground sensing circuit (34). The AC plug (32) and the power socket (33) are respectively mounted two opposite sides of the housing (31) and electronically connected together. The AC plug (32) is used to insert into a wall outlet, so the power socket (33) is used to replace the wall outlet. The ground sensing circuit (34) is mounted inside the housing (31) and electronically to the AC plug (32) to sense that the status of grounding connection of the wall outlet and display a status by an indicator (35). Therefore, when a user uses a power plug of the electronic equipment into the power socket (33) of the grounding apparatus (30), the user can check the display of the inductor (35) firstly. However, the conventional grounding apparatus (30) is used for the wall outlet, the power socket is necessarily required to replace the wall outlet (33). Therefore, the grounding apparatus (30) is difficulty miniaturized. When the user inserts the conventional grounding apparatus to an AC outlet of the power strip, other AC outlets of the power strip are blocked by the conventional grounding apparatus (30). In addition, the conventional is not portable.

To overcome the shortcomings, the present invention provides a pocket grounding device without power socket for a power strip to mitigate or obviate the aforementioned problems.

### SUMMARY OF THE INVENTION

The main objective of the present invention is to provide a pocket grounding device without power socket.

The pocket grounding device without power socket has a casing, an AC plug and a circuit board. The AC plug is mounted in the casing and electronically connected to the circuit board. The circuit board has a ground detecting circuit having three ports respectively connected to the AC plug, an electronic switch connected between to two of the ports and a controlling terminal thereof connected to the last port, and an indicator exposed to the casing. The indictor is driven to light at a conductive condition of the electronic switch since the AC plug connected to an AC outlet of a power strip having good grounding connection. Therefore, a user checks the LED status to judge whether the AC power strip has good grounding connection.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a pocket grounding device without power socket in accordance with the present invention;

FIG. 2 is a perspective view of the pocket grounding device inserted to a voltage outlet of a power strip in accordance with the present invention;

FIG. 3 is a detailed circuit diagram of a first embodiment of the pocket grounding device in accordance with the present invention;

FIG. 4 is a detailed circuit diagram of a second embodiment of a pocket grounding device in accordance with the present invention; and

FIG. 5 is perspective view of a conventional grounding apparatus in accordance with the prior art.

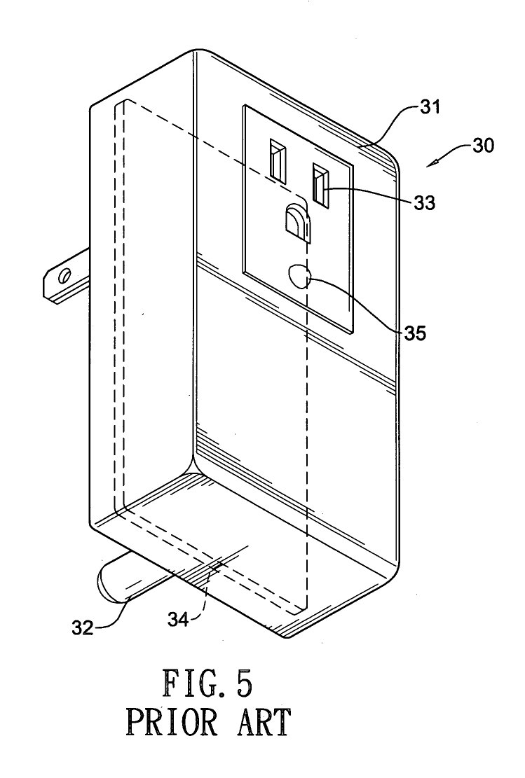

### DETAILED DESCRIPTION OF THE INVENTION

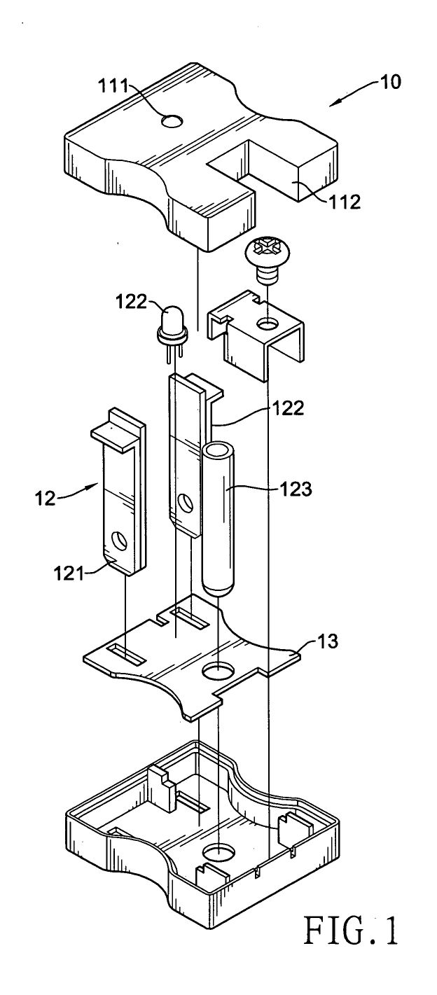

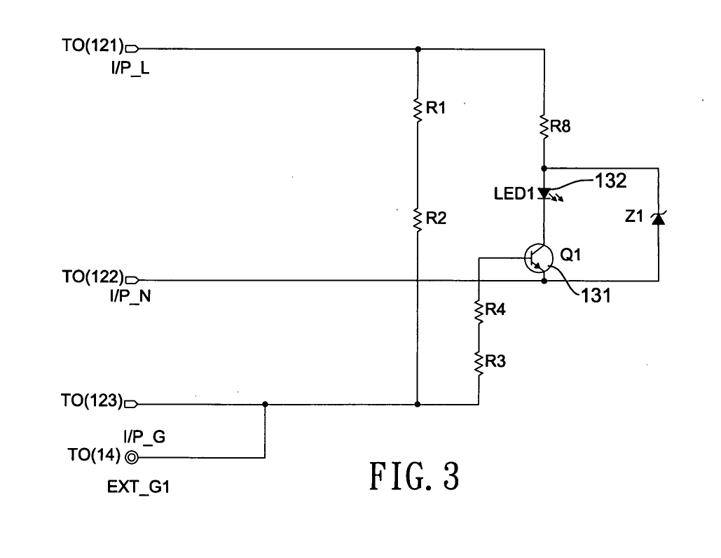

With reference to FIGS. 1 and 3, a first embodiment of a pocket grounding device (10) without power socket has a casing (11), a circuit board (13), an AC plug (12) and an external grounding port (14).

The casing (10) has two opposite faces, through hole (111) and an opening (112). The AC plug (12) mounted on the first face of the casing (11) and has a line blade (121), a neutral blade (122) and a ground blade (123).

The circuit board (13) has a ground detecting circuit having three ports (I/P_L, I/P_N, I/P_G), an electronic switch (131), an indicator (132) and a zener diode (Z1). The three ports (I/P_L, I/P_N, I/P_G) are respectively and electronically connected to the line blade (121), neutral blade (122) and a ground blade (123). The electronic switch (131) is connected between to the first and second ports (I/P_L, I/P_N) connected to the line blade (121) and the neutral blade (122). A controlling terminal of the electronic switch (131) is connected to the third port (I/P_G) connected to the ground blade (123). The indicator (132) may be an LED connected between the electronic switch (121) and the first port (I/P_L). The electronic switch (131) may be a BJT transistor having a collector, emitter and a base. That is, an anode terminal of the LED is connected to the first port (I/P_L) and a cathode terminal of the LED is connected to the collector of the electronic switch (131). The emitter of the electronic switch (131) is connected to the second port (I/P_N). The base of the electronic switch (131) is a controlling terminal and connected to the third port (I/P_G) through a first series of resistors (R3, R4). Further, the third port (I/P_G) is connected to the first port (I/P_L) through a second series of resistor (R1, R2). The zener diode (Z1) is connected between the anode terminal of the LED and the emitter of the electronic switch (131). The LED passes through the through hole (111) of the casing (11).

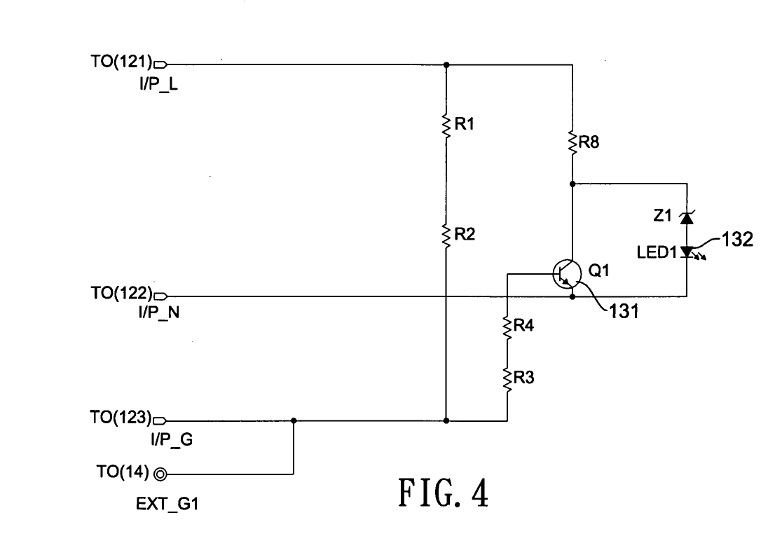

With reference to FIG. 4, a second embodiment of a pocket grounding device without power socket in accordance with present invention is similar to the first embodiment thereof. Most of elements of the second embodiment of the pocket grounding device, but the indicator is connected to the zener diode (Z1) in serial. When the indicator uses an LED, an anode terminal of the LED is connected to the zener diode (Z1) and the cathode of the LED is connected to the emitter of the electronic switch (131).

Based on the foregoing description, the grounding device does not require power socket and only displays grounding status by the indicator, the ground detecting circuit is simple and may be miniatured.

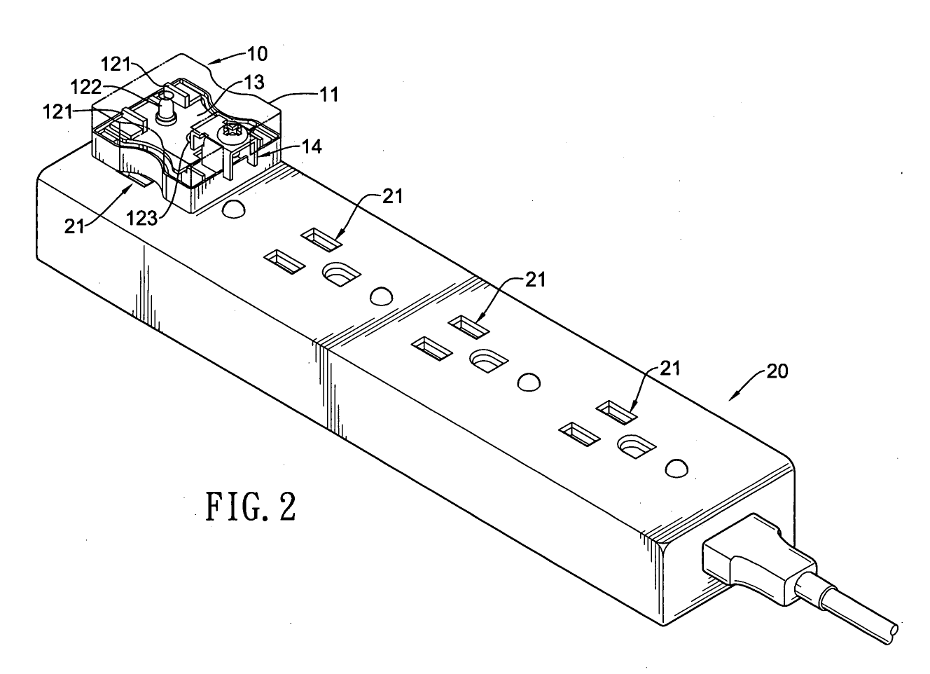

With reference to FIGS. 1 to 3, when the AC plug (12) is inserted into an AC outlet (21) of a power strip (20), the ground detecting circuit detects whether power strip (20) has good grounding connection. That is, in a positive cycle of the AC power from the AC outlet with good grounding connection, there is no potential difference between the first and third ports (I/P_L, I/P_G), so the electronic switch (131) is not driven to turn on. In a negative cycle of the AC power from the AC outlet with good grounding connection, AC current of the AC power passes through the second port, zener diode (Z1) and the first port (I/P_L), so the electronic switch (131) is not driven to turn on, too. However, in a positive cycle of the AC power from the AC outlet with a bed grounding connection or a ground floating condition, a potential difference between the first and third ports (I/P_L, I/P_G) is existed so as to drive the electronic switch (131) to turn on by the first and second series of resistors (R1 to R4). In a negative cycle of the AC power from the AC outlet with the bed grounding connection or the ground floating condition, the AC current of the AC power passes through the second port, zener diode (Z1) and the first port (I/P_L), so the electronic switch (131) is not driven to turn on. Therefore, the LED (132) is driven to light when the AC outlet has the bed grounding connection or the ground floating condition. A user checks the display status of the LED and then easily judges whether the AC power strip (20) has good grounding connection or not.

The external grounding port (14) is mounted in the casing (11), connected to the ground blade (123) and corresponding to the opening (112) of the casing (11). When the user adjusts that the power strip having bad or no grounding connection, the user may use an external grounding wire to connect to the external grounding port (14) of the present invention. In a preferred embodiment, the external grounding port (14) has a rectangular metal seat (141) having a thread hole (142) and a screw (143). The screw (143) is screwed into the thread hole (142) of the metal seat (141) to clip the grounding wire in the metal seat (141) securely. Therefore the grounding wire is electronically connected to the ground blade (123) of the AC plug (12). Further the AC plug (12) is inserted into the AC outlet (21), the grounding wire is also electronically connected to the AC outlet (21) to provide the power strip (20) a good grounding connection.

With reference to FIGS. 1, 2 and 4, when the AC plug (12) is inserted into an AC outlet (21) of a power strip (20), the ground detecting circuit detects whether power strip (20) has good grounding connection. In the second embodiment, there is no potential difference between the first and third ports (I/P_L, I/P_G), so the electronic switch (131) is not driven to turn on in a positive cycle of the AC power from the AC outlet with good grounding connection. At the time, the AC current of the AC power passes through the first port (I/P_L), the resistor (R6), the zener diode (Z1), the LED (132) and the second port (I/P_G), so the LED is driven to light. On the contrary, in a positive cycle of the AC power from the AC outlet with a bed grounding connection or a ground floating connection, a potential difference between the first and third ports (I/P_L, I/P_G) is existed so as to drive the electronic switch (131) to turn on by the first and second series of resistors (R1 to R4). Therefore, the LED (132) is not driven to light. Since a voltage of the second port (I/P_N) is larger than that of the first port (I/P_L), the electronic switch (131) is not driven to turn on and the LED is not driven to light. Therefore, in the second embodiment the LED (132) is driven to light when the AC outlet has the good grounding connection. A user checks the display status of the LED (132) and then easily judges whether the AC power strip (20) has good grounding connection or not.

Based on foregoing description, the grounding device also provides a good grounding function for the user. The user does not check or fix the grounding connection inside the power strip, and only uses the grounding wire to connect the external grounding port when the grounding device displays the power strap having bas or no grounding connection.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A pocket grounding device without power socket, comprising:
a casing has a first face, a second face and a through hole;
an AC plug mounted on the first face of the casing and having a line blade, a neutral blade and a ground blade; and
a circuit board having a ground detecting circuit and mounted in the casing, wherein the ground detecting circuit comprises:
a first port electronically connected to the line blade
a second port electronically connected to the neutral blade;
a third port electronically connected to the ground blade;
an electronic switch connected between to the first and second ports and a controlling terminal of the electronic switch connected to the third port; and
an indicator passing through the through hole of the casing, connected between the electronic switch and the first port, and driven to light by the electronic switch in conductive condition.

2. The pocket grounding device as claimed in claim 1, further comprising an external grounding port and the casing further having an opening, wherein the external grounding port is mounted in the casing, corresponding to the opening and electronically connected to the ground blade.

3. The pocket grounding device as claimed in claim 2, wherein the external grounding port comprises:
a metal seat having a thread hole adapted to receive a grounding wire; and
a screw screwed into the thread hole to adapt to clip the grounding wire in the metal seat securely.

4. The pocket grounding device as claimed in claim 2, wherein
the electronic switch is a BJT transistor having a collector, an emitter and a base used as the controlling terminal, wherein the emitter of the electronic switch is connected to the second port and the base is connected to the third port through a first series of resistors;
the indicator is an LED having:
an anode terminal of the LED connected to the first port; and
a cathode terminal of the LED connected to the collector of the electronic switch; and
the third port is connected to the first port through a second series of resistor.

5. The pocket grounding device as claimed in claim 4, wherein the ground detecting circuit further comprises a zener diode connected between the anode terminal of the LED and the emitter of the electronic switch.

6. A pocket grounding device without power socket, comprising:
a casing has a first face, a second face and a through hole;
an AC plug mounted on the first face of the casing and having a line blade, a neutral blade and a ground blade; and
a circuit board having a ground detecting circuit and mounted in the casing, wherein the ground detecting circuit comprises:
a first port electronically connected to the line blade
a second port electronically connected to the neutral blade;
a third port electronically connected to the ground blade;
an electronic switch connected between to the first and second ports and a controlling terminal of the electronic switch connected to the third port; and
an indicator passing through the through hole of the casing, connected between the first and the second ports.

7. The pocket grounding device as claimed in claim 6, further comprising an external grounding port and the casing further having an opening, wherein the external grounding port is mounted in the casing, corresponding to the opening and electronically connected to the ground blade.

8. The pocket grounding device as claimed in claim 7, wherein the external grounding port comprises:
a metal seat having a thread hole adapted to receive a grounding wire; and
a screw screwed into the thread hole to adapt to clip the grounding wire in the metal seat securely.

9. The pocket grounding device as claimed in claim 8, wherein the ground detecting circuit further comprises a zener diode connected to the indicator in serial.

10. The pocket grounding device as claimed in claim 9, wherein
the electronic switch is a BJT transistor having a collector, an emitter and a base used as the controlling terminal, wherein the emitter of the electronic switch is connected to the second port and the base is connected to the third port through a first series of resistors;
the indicator is an LED having:
an anode terminal of the LED connected to the first port through the zener diode; and
a cathode terminal of the LED connected to the collector of the emitter switch; and
the third port is connected to the first port through a second series of resistor.
